(19) United States
(12) Patent Application Publication
(10) Pub. No.: US 2014/0151818 A1
(43) Pub. Date: Jun. 5, 2014

(54) SEMICONDUCTOR DEVICE WITH A SILICON DIOXIDE GATE INSULATION LAYER IMPLANTED WITH A RARE EARTH ELEMENT AND METHODS OF MAKING SUCH A DEVICE

(71) Applicant: GLOBALFOUNDRIES INC., Grand Cayman (KY)

(72) Inventors: Jan Hoentschel, Dresden (DE); Stefan Flachowsky, Dresden (DE)

(73) Assignee: GLOBALFOUNDRIES INC., Grand Cayman (KY)

(21) Appl. No.: 13/689,936

(22) Filed: Nov. 30, 2012

(51) Int. Cl. H01L 21/28; H01L 29/78

(52) U.S. Cl. CPC H01L 21/28017; H01L 29/78
USPC 257/411; 438/585

(57) ABSTRACT

One illustrative method disclosed herein includes forming a gate insulation layer on a semiconducting substrate, performing an ion implantation process to implant a rare earth element into the gate insulation layer, and forming a silicon-containing gate electrode above the gate insulation layer comprising the implanted rare earth element. One illustrative device disclosed herein includes a gate insulation layer positioned on a semiconducting substrate, wherein the gate insulation layer is comprised of silicon dioxide and a rare earth element, and a silicon-containing gate electrode positioned on the gate insulation layer.

### BACKGROUND OF THE INVENTION

1. Field of the Invention

Generally, the present disclosure generally relates to the manufacture of sophisticated semiconductor devices, and, more specifically, to a semiconductor device with a silicon dioxide gate insulation layer that includes an implanted rare earth element and a silicon-based gate electrode, and to various methods of making such a device.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout. Metal oxide field effect transistors (MOSFETs or FETs) represent one important type of circuit element that substantially determines performance of the integrated circuits. A FET (whether an NFET or a PFET) is a device that typically includes a source region, a drain region, a channel region that separates the source region and the drain region, and a gate electrode positioned above the channel region. A gate insulation layer is positioned between the gate electrode and the channel region that will be formed in the substrate. Electrical contacts are made to the source and drain regions, and current flow through the FET is controlled by controlling the voltage applied to the gate electrode. If there is no voltage applied to the gate electrode, then there is no current flow through the device (ignoring undesirable leakage currents, which are relatively small). However, when an appropriate voltage is applied to the gate electrode, the channel region becomes conductive, and electrical current is permitted to flow between the source region and the drain region through the conductive channel region. Traditionally, FETs have been substantially planar devices, but similar principles of operation apply to more three-dimensional FET structures, devices that are typically referred to as FinFETs.

For many early device technology generations, the gate structures of most transistor elements have been comprised of silicon-based materials, such as a silicon dioxide and/or silicon oxynitride gate insulation layer, in combination with a polysilicon gate electrode, i.e., so-called SiON/Poly-Si-Gate technology devices. Historically, the channel length of SiON/Poly-Si-Gate transistor devices was reduced to increase the electrical performance characteristics of the transistors, e.g., to improve the drive current capability of the device and to increase its switching speed. However, with these traditional SiON/Poly-Si-Gate transistor devices, the reduction in channel length reached a limit where undesirable so-called short channel effects caused a decrease in device performance, e.g., an increase in off-state leakage currents. Thus, many newer generation devices employ gate structures comprised of alternative materials in an effort to avoid such short channel effects that were associated with the use of SiON/Poly-Si-Gate transistor devices with very small channel lengths. For example, in some aggressively scaled transistor elements, which may have channel lengths on the order of approximately 14-32 nm, gate structures having a so-called high-k dielectric/metal gate (HK/MG) configuration have been shown to provide significantly enhanced operational characteristics over the traditional SiON/Poly-Si-Gate transistor devices.

Depending on the specific overall device requirements, several different high-k materials—i.e., materials having a dielectric constant, or k-value, of approximately 10 or greater—have been used with varying degrees of success for the gate insulation layer in HK/MG gate structures. For example, in some transistor element designs, a high-k gate insulation layer, which may include tantalum oxide (Ta₂O₅), hafnium oxide (HfO₂), zirconium oxide (ZrO₂), titanium oxide (TiO₂), aluminum oxide (Al₂O₃), hafnium silicates (HfSiOₓ) and the like, was formed by depositing the high-k material on the substrate. Thereafter, one or more non-polysilicon metal gate electrode materials—i.e., a metal gate stack—was used in HK/MG configurations so as to control the work function of the transistor. These metal gate electrode materials may include, for example, one or more layers of titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi) and the like. Silicon-based gate electrode materials could not be used with such high-k gate insulation layers because the resulting transistors exhibited a threshold voltage level that was too high, primarily due to a degradation in the charge carrying capability of the channel.

The present disclosure is directed to a semiconductor device with a silicon dioxide gate insulation layer that includes an implanted rare earth element and a silicon-based gate electrode, and to various methods of making such a device, that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a semiconductor device with a silicon dioxide gate insulation layer that includes an implanted rare earth element and a silicon-based gate electrode, and to various methods of making such a device. One illustrative method disclosed herein includes forming a gate insulation layer on a semiconducting substrate, performing an ion implantation process to implant a rare earth element into the gate insulation layer, and forming a silicon-containing gate electrode above the gate insulation layer comprising the implanted rare earth element.

One illustrative device disclosed herein includes a gate insulation layer positioned on a semiconducting substrate, wherein the gate insulation layer is comprised of silicon dioxide and a rare earth element, and a silicon-containing gate electrode positioned on the gate insulation layer.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1E depict various illustrative methods disclosed herein for manufacturing a novel semiconductor device with a silicon dioxide gate insulation layer that includes an implanted rare earth element and a silicon-based gate electrode.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to a semiconductor device with a silicon dioxide gate insulation layer that includes an implanted rare earth element and a silicon-based gate electrode, and to various methods of making such a device. As will be readily apparent to those skilled in the art upon a complete reading of the present application, the presently disclosed methods and devices may be applied to a variety of different technologies, e.g., NFET, PFET, CMOS, etc., and they may be readily employed with a variety of integrated circuit devices, including, but not limited to, logic devices, memory devices, etc. With reference to the attached figures, various illustrative embodiments of the devices disclosed herein will now be described in more detail.

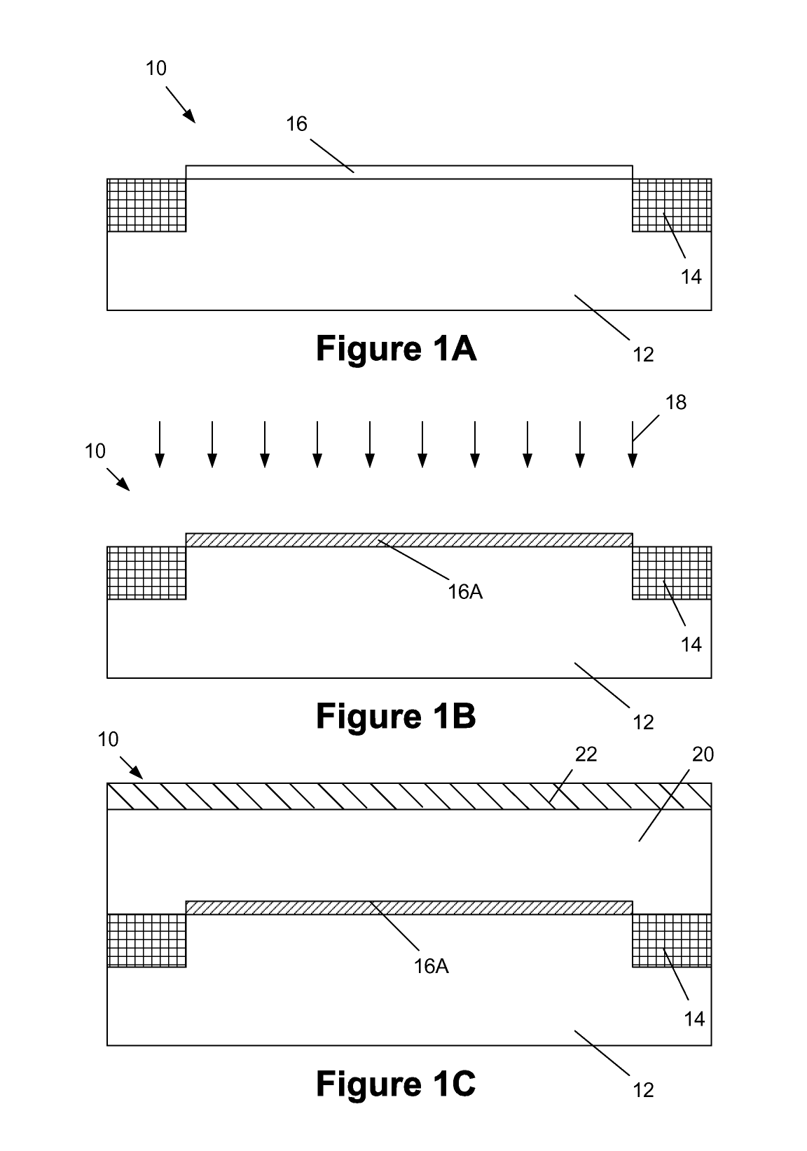

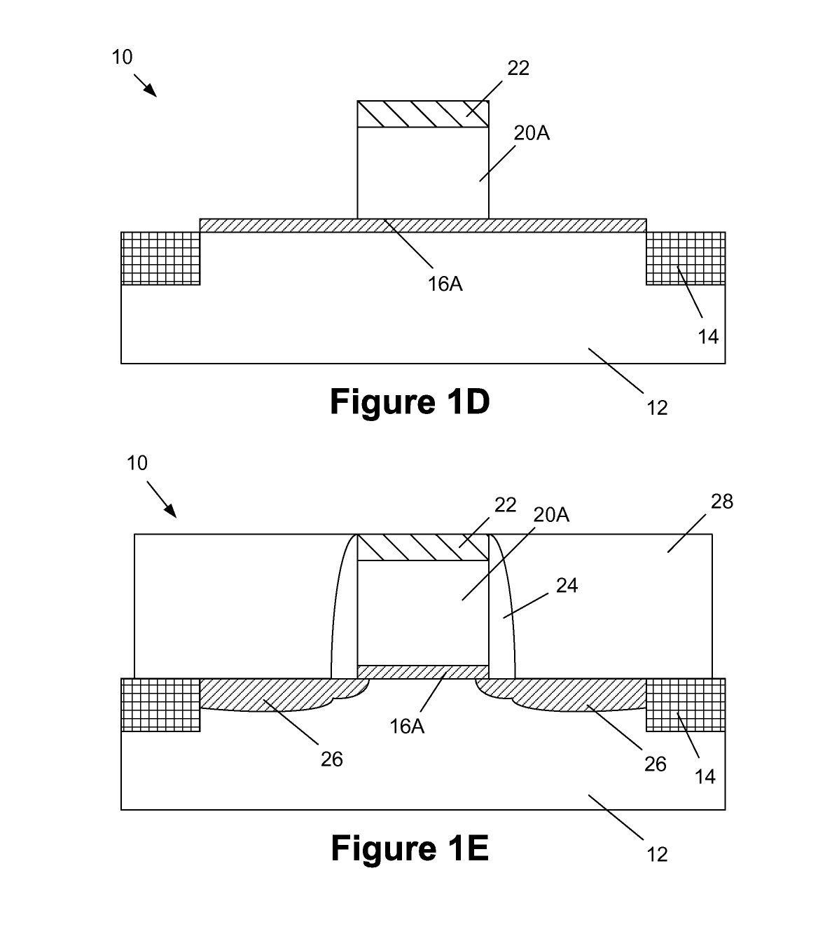

FIG. 1A depicts one illustrative embodiment of a transistor 10 at an early stage of manufacture. The transistor 10 will be formed in and above a semiconducting substrate 12 in an active area defined by a shallow trench isolation structure 14. The substrate 12 may have a variety of configurations, such as the depicted bulk silicon configuration. The substrate 12 may also have a silicon-on-insulator (SOI) configuration that includes a bulk silicon layer, a buried insulation layer and an active layer, wherein semiconductor devices are formed in and above the active layer. Thus, the terms “substrate” or “semiconducting substrate” should be understood to cover all forms of semiconductor structures.

At the point of fabrication depicted in FIG. 1A, a gate insulation layer 16 has been formed on the active region. In one illustrative example, the gate insulation layer 16 may be a layer of silicon dioxide that is formed by performing a thermal oxidation process. The thickness of the gate insulation layer 16 may vary depending upon the particular application. In one illustrative embodiment, the gate insulation layer 16 may be a layer of silicon dioxide having a thickness of about 1.5-2 nm.

Next, as shown in FIG. 1B, an ion implantation process 18 is performed to implant a rare earth element into the gate insulation layer 16, wherein the reference number has been changed to 16A and cross-hatching has been added to reflect the implanting of the rare earth element into the gate insulation layer. Examples of rare earth elements that may be used during the implantation process 18 include, but are not limited to, hafnium, zirconium, lanthanum, tantalum, etc. In general, the energy level during the implantation process 18 should be relatively low, e.g., less than about 1 keV, to insure that the rare earth element does not penetrate into the channel region or that such penetration is very limited. In one illustrative example, the implantation process 18 may be performed using a dose of about 1e¹³-1e¹⁴ atoms/cm². In one example, the concentration of the implanted rare earth element in the gate insulation layer 16A may be about 1% (by volume). The implantation of the rare earth element into the gate insulation layer has the effect of increasing the k value of the gate insulation layer. For example, in the case where the gate insulation layer 16, as initially formed, is a layer of thermally grown silicon dioxide (with a k value of about 3.8), the introduction of the implanted rare earth material will increase the k value of the gate insulation layer 16A to a value of 5 or greater.

Next, as shown in FIG. 1C, a silicon-based or silicon-containing layer of gate electrode material 20, e.g., polysilicon, amorphous silicon, and a gate cap layer 22, e.g., silicon nitride, are formed above the gate insulation layer 16A. The layers of material 20, 22 may be formed by performing a variety of process operations that are well known to those skilled in the art, e.g., an atomic layer deposition (ALD) process, a chemical vapor deposition (CVD) process, plasma enhanced versions of such processes, etc. The thickness of the layers 20, 22 may vary depending upon the particular application.

FIG. 1D depicts the device 10 after basic gate patterning operations have been performed. More specifically, a patterned etch mask (not shown), such as a patterned layer of photoresist material, was formed above the gate cap layer 22. Thereafter, one or more etching processes were performed to produce the basic gate electrode 20A for the device 10.

FIG. 1E depicts the device 10 after several traditional manufacturing operations have been performed. As shown therein, sidewall spacers 24 (e.g., silicon nitride), source/drain regions 26 and a layer of insulating material 28, e.g., silicon dioxide, have been formed on the device 10 using traditional techniques. Of course, those skilled in the art will recognize that there are other features of the transistor 10 that are not depicted in the drawings for purposes of clarity. For example, so-called halo implant regions are not depicted in the drawings, as well as various layers or regions of silicon-germanium that are typically found in high-performance PFET transistors.

Using the novel techniques disclosed herein provide several advantages. First, since the novel device disclosed herein involves use of traditional silicon-based materials, process integration will be easier and manufacturing costs should be less than those associated with the production of traditional high-k/metal gate devices. Moreover, the techniques disclosed herein allow another means of controlling the threshold voltage of the device 10 by controlling the amount of the implanted rare earth element and which element is selected for implantation. In the case of CMOS applications, the methods disclosed herein allows for the formation of different gate insulation layers on different device types. For example, using appropriate masking layers, one rare earth element may be implanted on P-type devices, while another rare earth element may be implanted on N-type devices.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a transistor, comprising:
forming a gate insulation layer on a semiconducting substrate;
performing an ion implantation process to implant a rare earth element into said gate insulation layer; and
forming a silicon-containing gate electrode above said gate insulation layer comprising said implanted rare earth element.

2. The method of claim 1, wherein said rare earth element is one of hafnium, zirconium, lanthanum or tantalum.

3. The method of claim 1, wherein said ion implantation process is performed at an energy level less than 1 keV.

4. The method of claim 1, wherein said ion implantation process is performed using a dose of said rare earth element of about 1e¹³-1e¹⁴ atoms/cm².

5. The method of claim 1, wherein forming said gate insulation layer comprises performing a thermal oxidation process to form a gate insulation layer comprised of silicon dioxide on said semiconducting substrate.

6. The method of claim 1, wherein said silicon-containing gate electrode is comprised of polysilicon or amorphous silicon.

7. The method of claim 1, wherein said gate insulation layer comprising said implanted rare earth element has a k value of 5 or greater.

8. The method of claim 1, wherein forming said silicon-containing gate electrode comprises:
depositing a layer of silicon-containing material on said gate insulation layer; and
performing an etching process to pattern said layer of silicon-containing material.

9. The method of claim 1, wherein a concentration of said rare earth element in said gate insulation layer is less than about 1% by volume.

10. A method of forming a transistor, comprising:
performing a thermal oxidation process to form a silicon dioxide gate insulation layer on a semiconducting substrate;
performing an ion implantation process to implant a rare earth element into said silicon dioxide gate insulation layer such that said silicon dioxide gate insulation layer comprising said implanted rare earth element has a k value of 5 or greater; and
forming a silicon-containing gate electrode on said gate insulation layer comprising said implanted rare earth element.

11. The method of claim 10, wherein said rare earth element is one of hafnium, zirconium, lanthanum or tantalum.

12. The method of claim 10, wherein said silicon-containing gate electrode is comprised of polysilicon or amorphous silicon.

13. The method of claim 10, wherein forming said silicon-containing gate electrode comprises:
depositing a layer of silicon-containing material on said gate insulation layer; and
performing an etching process to pattern said layer of silicon-containing material.

14. A method of forming a transistor, comprising:
performing a thermal oxidation process to form a silicon dioxide gate insulation layer on a semiconducting substrate;
performing an ion implantation process to implant a rare earth element into said gate insulation layer, wherein said ion implantation process is performed using a dose of said rare earth element of about 1e¹³-1e¹⁴ atoms/cm² and an energy level less than 1 keV; and
forming a silicon-containing gate electrode on said gate insulation layer comprising said implanted rare earth element.

15. The method of claim 14, wherein said rare earth element is one of hafnium, zirconium, lanthanum or tantalum.

16. The method of claim 14, wherein said silicon-containing gate electrode is comprised of polysilicon or amorphous silicon.

17. The method of claim 14, wherein forming said silicon-containing gate electrode comprises:
depositing a layer of silicon-containing material on said gate insulation layer; and
performing an etching process to pattern said layer of silicon-containing material.

18. The method of claim 14, wherein said gate insulation layer comprising said implanted rare earth element has a k value of 5 or greater.

19. A transistor, comprising:
a gate insulation layer positioned on a semiconducting substrate, said gate insulation layer comprising silicon dioxide and a rare earth element, wherein said gate insulation layer has a k value of 5 or greater; and
a silicon-containing gate electrode positioned on said gate insulation layer.

20. The device of claim 19, wherein said rare earth element is one of hafnium, zirconium, lanthanum or tantalum.

21. The device of claim 19, wherein said gate insulation layer is a thermally grown layer of silicon dioxide.

22. The device of claim 19, wherein said silicon-containing gate electrode is comprised of polysilicon or amorphous silicon.

23. The device of claim 19, wherein a concentration of said rare earth element in said gate insulation layer is less than about 1% by volume.

24. A transistor, comprising:
a gate insulation layer positioned on a semiconducting substrate, said gate insulation layer comprising silicon dioxide and a rare earth element, wherein a concentration of said rare earth element in said gate insulation layer is less than about 1% by volume and wherein said gate insulation layer has a k value greater than 5; and
a silicon-containing gate electrode positioned on said gate insulation layer.

25. The device of claim 24, wherein said silicon-containing gate electrode is comprised of polysilicon or amorphous silicon.

26. The device of claim 24, wherein said rare earth element is one of hafnium, zirconium, lanthanum or tantalum
